(19) United States
(12) Patent Application Publication
(10) Pub. No.: US 2015/0186278 A1
(43) Pub. Date: Jul. 2, 2015

(54) RUNTIME PERSISTENCE

(71) Applicants: SARATHY JAYAKUMAR, Portland, OR (US); MOHAN J. KUMAR, Aloha, OR (US); KRISHNAKANTH V. SISTLA, Beaverton, OR (US)

(72) Inventors: SARATHY JAYAKUMAR, Portland, OR (US); MOHAN J. KUMAR, Aloha, OR (US); KRISHNAKANTH V. SISTLA, Beaverton, OR (US)

(21) Appl. No.: 14/141,255

(22) Filed: Dec. 26, 2013

(51) Int. Cl. G06F 12/08; G11C 14/00; G06F 12/02

(52) U.S. Cl. CPC G06F 12/0833; G06F 12/0246; G11C 14/009

(57) ABSTRACT

Apparatus, systems, and methods to manage memory operations are described. In one embodiment, a controller is coupled to a processor unit, and comprising logic to block additional transactions on the processor unit, initiate a cache flush to flush data from cache memory coupled to the processor unit to a memory controller buffer, block incoming data from the cache memory, and initiate a buffer flush to flush data from the memory controller buffer to a nonvolatile memory. Other examples are also disclosed and claimed.

### FIELD

The present disclosure generally relates to the field of electronics. More particularly, some examples of the invention generally relate to techniques to implement runtime persistence in electronic devices.

### BACKGROUND

It may be useful for electronic devices to store data in a non-volatile memory such that the data remains intact when power to the electronic device is turned off or otherwise lost. The non-volatile memory device for storing digital information in an array of non-volatile memory cells may be included in a Non-Volatile Dual In-line Memory Module (NVDIMM). Digital information stored in the non-volatile memory (for example, NAND/NOR flash memory) persists in the memory during power loss or system failures. After power to the electronic device is restored, the electronic device can access the stored digital data from the NVDIMM.

Logic executing in an electronic device can modify data stored in non-volatile memory. For example, logic executing on a processor of the electronic device may update a data element stored in non-volatile memory. In such an instance, the logic retrieves a copy of the data element stored in non-volatile memory and stores a copy of the data element in a volatile memory, e.g., cache memory.

The logic may update the data while the data element is stored in volatile memory. Subsequent to completing any changes to the copy of the data element stored in volatile memory, the logic may return the updated data element to non-volatile memory.

If a failure such as loss of power occurs prior to complete storage of modified data element non-volatile memory, it is possible that none or only a portion of data element will be written to non-volatile memory. In such an instance, the power failure results in loss of data because the modified data element is not properly stored in non-volatile memory.

### BRIEF DESCRIPTION OF THE DRAWINGS

The detailed description is provided with reference to the accompanying figures. The use of the same reference numbers in different figures indicates similar or identical items.

FIG. 1 is a schematic, block diagram illustration of components of apparatus to implement runtime persistence in accordance with various examples discussed herein.

FIG. 2 is a schematic block diagram of a processing environment which may be adapted to implement runtime persistence in accordance with various examples discussed herein.

FIG. 3 is a schematic illustration of a persistent memory range register, in accordance with various examples discussed herein.

FIGS. 4 and 5 are flowcharts illustrating operations in a method to implement runtime persistence in accordance with various examples discussed herein.

FIGS. 6-10 are schematic, block diagram illustrations of electronic devices which may be adapted to implement runtime persistence in accordance with various examples discussed herein.

### DETAILED DESCRIPTION

In the following description, numerous specific details are set forth in order to provide a thorough understanding of various examples. However, various examples of the invention may be practiced without the specific details. In other instances, well-known methods, procedures, components, and circuits have not been described in detail so as not to obscure the particular examples of the invention. Further, various aspects of examples of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Described herein are techniques to implement runtime persistence in processing systems of electronic devices. Some examples described herein may find utility in multi-core processor devices which include integrated cache memory. More particularly, some examples described herein may find utility in electronic devices which implement automatic DIMM refresh (ADR) procedures to flush processor cache to nonvolatile memory.

In brief, multi-core processor devices may flush processor cache to nonvolatile memory. In the event of a power failure, power is maintained for a brief period of time, sometimes referred to as a “hold up time”, of a few milliseconds by a backup power source such as capacitors. During the hold up time the data stored in processor cache is written to nonvolatile memory.

Processor cache sizes are increasing rapidly. Depending upon factors such as the memory topology and communication link speed, processor cache can overwhelm the capacity of the system architecture to write cache data to nonvolatile memory within the hold up time. This, in turn, can result in loss of data.

Techniques described herein address this issue by implementing a runtime persistence procedure in which software executing on a processor triggers a cache flush to nonvolatile memory. In some instances the cache flush may be triggered in response to one or more conditions or events. For example, software may trigger a cache flush in response to a time threshold elapsing or in response to environmental conditions. Alternatively, software may trigger a cache flush after writing a predetermined amount of data to memory or after particularly important data is written to memory. The particular conditions which trigger a cache flush are not critical.

In some examples the software initiates a cache flush process by writing to a specific register in a memory of a processor core. In response to the write, a controller in the processor core blocks further transactions in the processor core then initiates a cache flush process. In some examples the controller implements a targeted cache flush operation which flushes only data that is targeted to nonvolatile memory. The data state of cached memory that is flushed is changed to an Exclusive state so that subsequent read operations do not incur a performance penalty. Cached data is flushed to a write queue in a memory controller, which then writes the data to nonvolatile memory. The core can then be released for further processing.

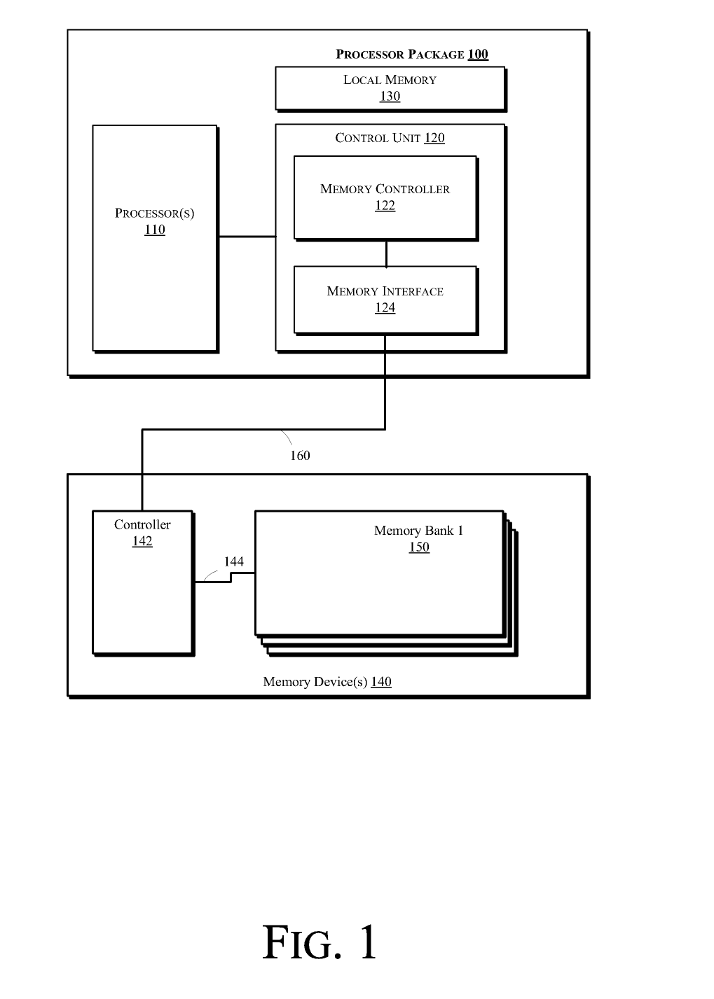

Additional structural features and operations to implement runtime persistence will be described with reference to FIGS. 1-5, below.

FIG. 1 is a schematic, block diagram illustration of components of apparatus to implement runtime persistence in accordance with various examples discussed herein. Referring to FIG. 1, in some examples a processor 100 may comprise one or more processors 110 coupled to a control unit 120 and a local memory 130. Control unit 120 comprises a memory controller 122 and a memory interface 124.

Memory interface 124 is coupled to one or more remote memory devices 140 by a communication bus 160. Memory device 140 may comprise a controller 142 and one or more memory banks 150. In various examples, at least some of the memory banks 150 may be implemented using nonvolatile memory, e.g., phase change memory, NAND (flash) memory, ferroelectric random-access memory (FeTRAM), nanowire-based non-volatile memory, memory that incorporates memristor technology, a static random access memory (SRAM), three dimensional (3D) cross point memory such as phase change memory (PCM), spin-transfer torque memory (STT-RAM) or NAND memory. In some example the memory device(s) 140 may comprise one or more nonvolatile direct in-line memory modules (NVDIMMs) coupled to a memory channel 144 which provides a communication link to controller 142. The specific configuration of the memory bank(s) 150 in the memory device(s) 140 is not critical.

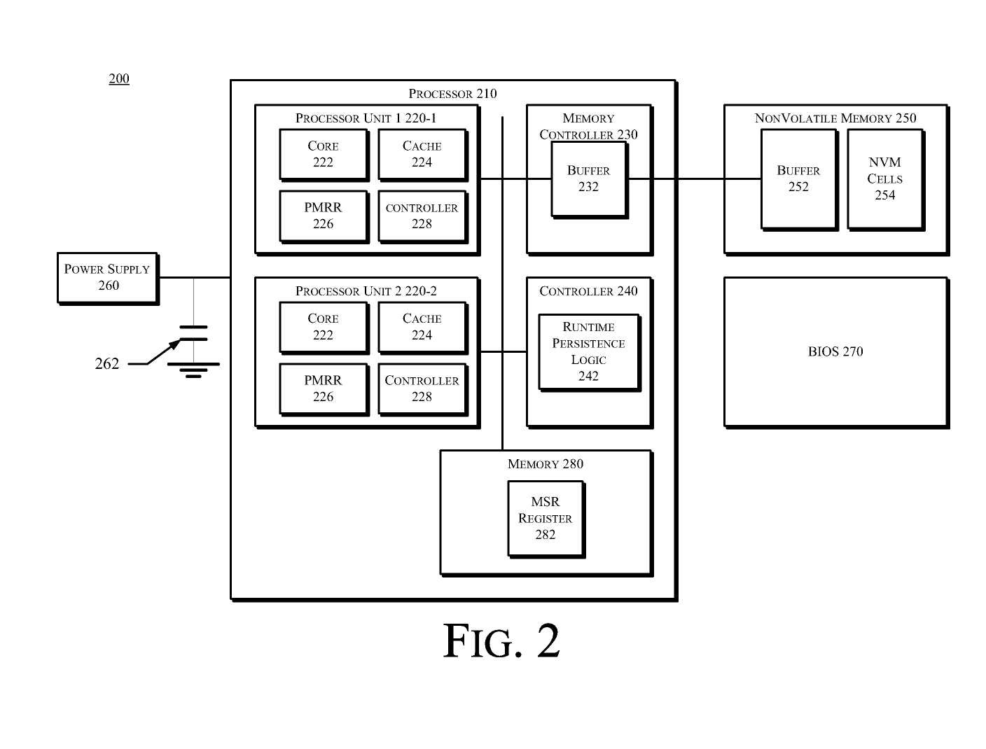

FIG. 2 is a schematic block diagram of a processing environment which may be adapted to implement runtime persistence in accordance with various examples discussed herein. Referring to FIG. 2, a processor environment 200 may comprise at least one processor 210 coupled to a power supply 260 and to nonvolatile memory 250. An energy storage device 262 such as one or more capacitors stores a portion of the power provided by power supply 260. As described above, in the event of a power failure such as a condition in which the power supply 160 no longer outputs power in a proper voltage range to power processor environment 200, the energy stored in energy storage resource 262 continues to provide appropriate power to processor 210 for at least a limited amount of holdup time.

Processor 210 may comprise one or more processor units 220-1, 220-2, which may be referred to herein collectively by reference numeral 220. Processor 210 may further comprise a memory controller 230 having a buffer 232, a controller 240, and a memory 280. Each processor unit 220 may comprise a core 222, cache memory 224, a persistent memory range register (PMRR) 226, and a cache controller 228. Memory 280 may include a model specific register (MSR) and a persistent memory range register (PMRR) 226.

The processor core(s) 222 execute logic instructions to implement one or more processing threads. Core(s) 222 may work independently or cooperatively to define a multi-core processing environment. Cache 224 may be implemented as multi-level fast access cache defined in volatile memory, typically on the same die as the core(s) 222.

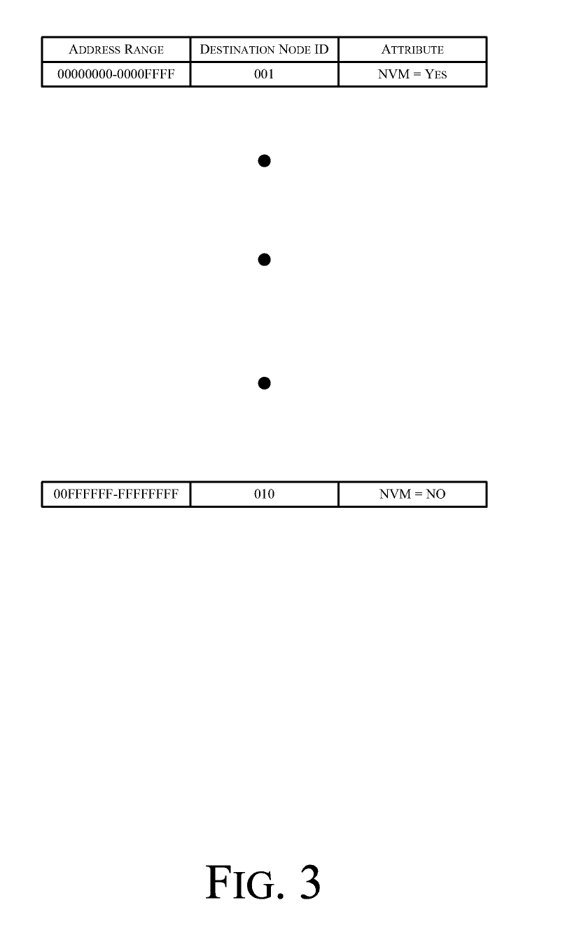

The PMRR 226 may be established by the system basic input/output system (BIOS) 270, e.g., during a system configuration process, based on factors such as the configuration of the processor environment, the memory topology, interleaving rules, and the like. Referring to FIG. 3, In some examples the PMRR 226 may include a plurality of entries which map memory address ranges to memory types. Further, each entry the PMRR may include a data field which designates whether an address range maps to nonvolatile memory or to volatile memory.

As described briefly above, in some examples the processing units 220 include a cache controller 228 that implements flush logic which, when executed, implements a cache flush routine to flush cache 224 to nonvolatile memory 250. The operations described herein may find particular utility in the context of an ADR routine implemented in response to a failure or interruption of power supply. However, the operations described herein may provide utility in contexts other than power failure or power interruption. Further, controller 240 may comprise runtime persistence logic 242 to trigger a cache flush routine. In some examples runtime persistence logic 242 may be implemented as logic embedded in controller 242. In alternate embodiments runtime persistence logic 242 may be implemented as logic instructions stored in a non-transitory computer readable medium, e.g., software, that may be stored in memory 280 and executed by processor 210.

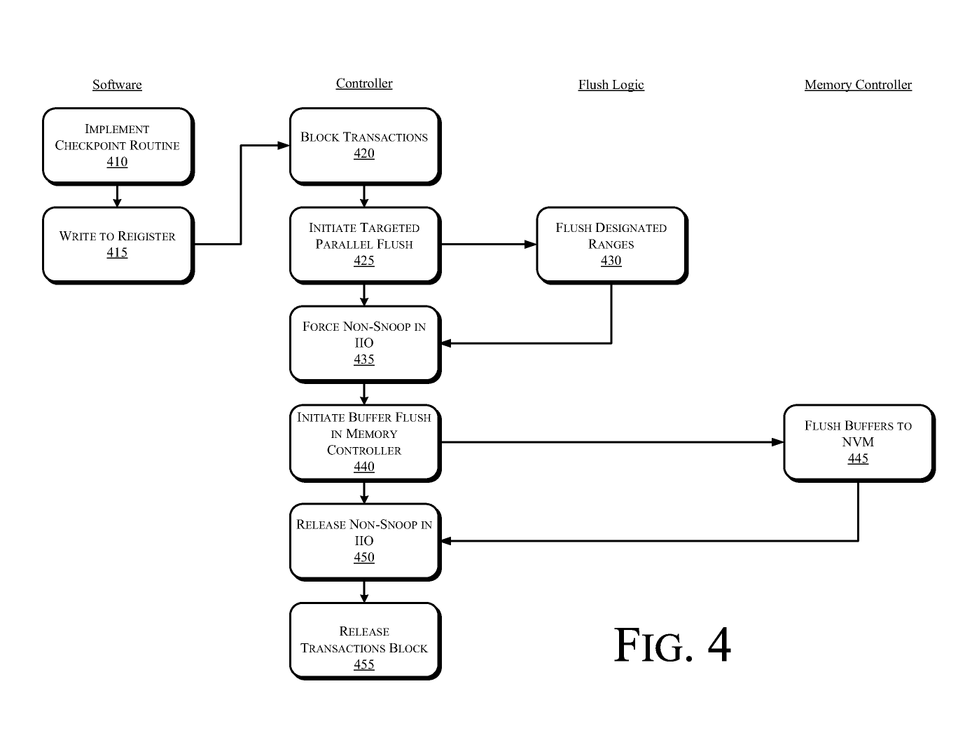

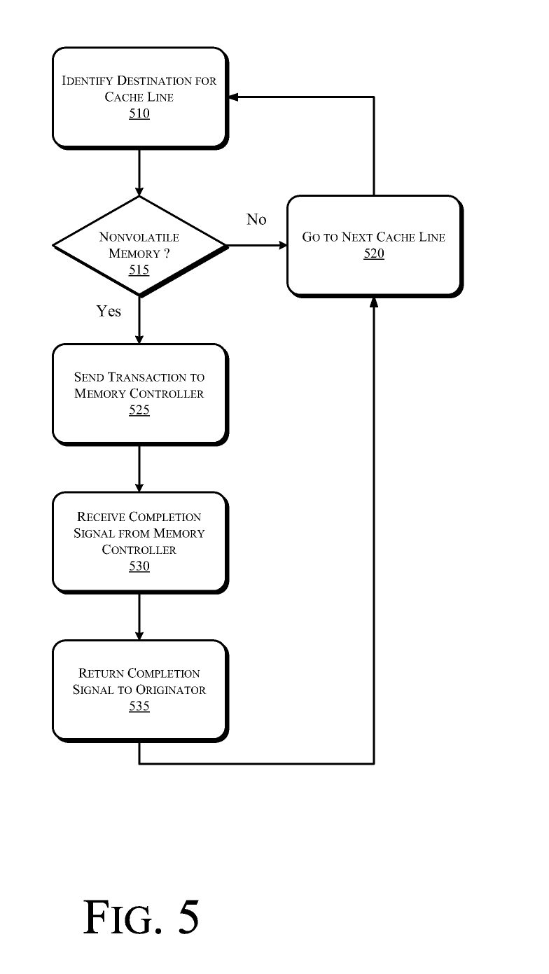

Operations to implement a runtime persistence routine will be described with reference to FIGS. 4 and 5. Referring first to FIG. 4, at operation 410 software executing on processor 210 implements a checkpoint routine. At operation 415 the software writes to a register 282 in memory 280.

The write operation triggers the controller 240 to implement a selective cache flush routine in processor 210. At operation 420 the controller 240 blocks additional cache transactions on the processor 210. For example, the controller 240 may place the processor cores 222 into a low-power state. At operation 425 the controller 240 initiates a targeted parallel cache flush of the cache 224 of the respective processor units to flush data from the cache 224 to buffer 232 in memory controller 230.

In some examples the cache flush is executed (operation 430) in parallel by logic in the respective controllers 228 of the processor units 220. One example of a cache flush is depicted in FIG. 5. Referring briefly to FIG. 5, at operation 510 the cache controller 228 identifies a destination for a cache line. For example, in some embodiments the cache flush logic in the cache controller 228 may query the PMRR register depicted in FIG. 3 to identify the destination for the transaction.

At operation 515 the cache controller 228 determines whether the destination for the cache line identified in operation 410 is nonvolatile memory. By way of example, cache flush logic in the cache controller 228 may consult the attribute column of the PMRR register depicted in FIG. 3 to determine whether the target destination is nonvolatile memory.

If, at operation 515, the destination for the transaction is not nonvolatile memory then control passes to operation 420 and the cache flush operation moves to the next line in cache. Control then passes back to operation 510 and the next cache line is evaluated to determine whether the cache line is mapped to nonvolatile memory.

By contrast, if at operation 515 the destination for the transaction is nonvolatile memory then control passes to operation 525 440 and the cache controller 228 sends the transaction to the memory controller 230. The data from cache 224 may be stored in the buffer 232 in memory controller then written to nonvolatile memory 250. When the data is received in nonvolatile memory 250 it may be stored temporarily in buffer 252 before being written to nonvolatile memory cells 254, whereupon the nonvolatile memory 250 may return a completion signal to the memory controller 230, which, in turn, forwards a completion signal to the cache controller 228.

At operation 530 the cache controller receives the completion signal from the memory controller 230, and at operation 450 the cache controller 228 returns a completion signal to the originator of the cache transaction. Control then passes back to operation 520 and the controller processes the next cache line. This process repeats until the contents of the cache 224 that are mapped to nonvolatile memory are flushed.

Referring back to FIG. 4, once the flush logic is finished control passes back to operation 435 and the controller 228 forces the processor unit 220 into a non-snoop mode such that inbound data from input/output (I/O) devices bypasses the cache 224 and is written directly to memory. This prevents the cache 224 from being contaminated by I/O operations.

At operation 440 the controller 228 initiates a buffer flush process in the memory controller 230. At operation 445 the memory controller 230 flushes the contents of memory buffer 232 to nonvolatile memory 250.

At operation 450 the controller releases the processor unit 220 from the non-snoop mode such that data from I/O operations can flow to cache 224, and at operation 450 the controller 228 releases the transaction block, e.g., by removing the controller from the low-power state.

Thus, the operations depicted in FIGS. 4-5 enables a processing unit to implement a runtime persistence procedure which flushes only cache transactions that are targeted to nonvolatile memory.

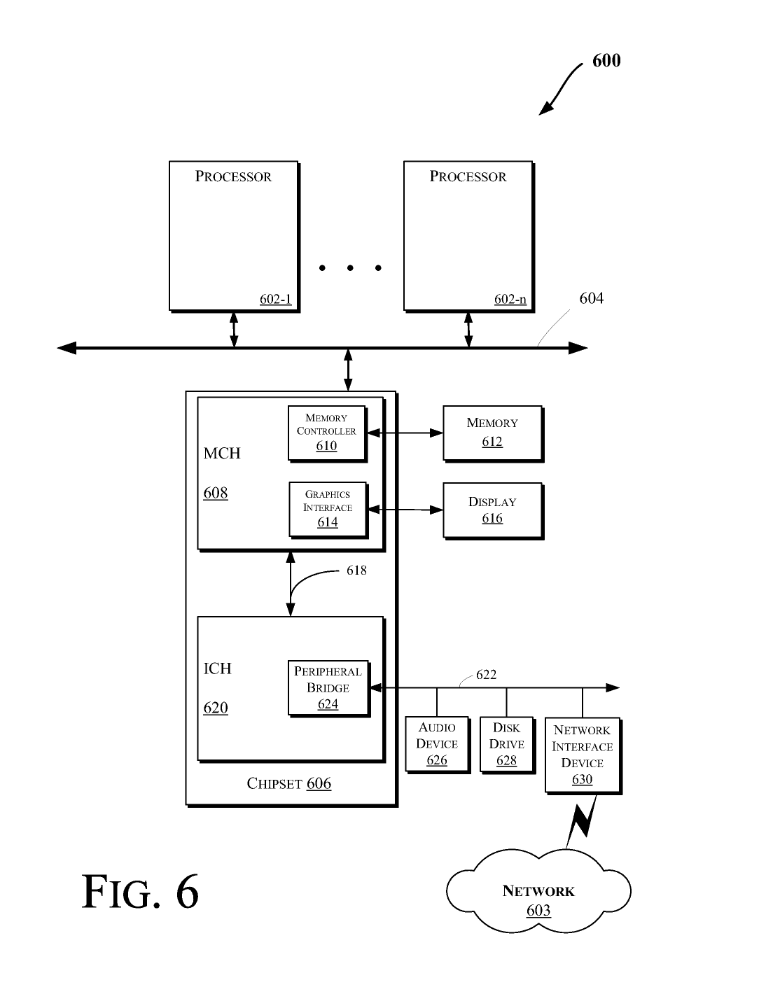

As described above, in some examples the electronic device may be embodied as a computer system. FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. In an embodiment, one or more of the processors 602 may be the same or similar to the processors 102 of FIG. 1.

A chipset 606 may also communicate with the interconnection network 604. The chipset 606 may include a memory control hub (MCH) 608. The MCH 608 may include a memory controller 610 that communicates with a memory 612. The memory 612 may store data, including sequences of instructions, that may be executed by the CPU 602, or any other device included in the computing system 600. In one embodiment of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The MCH 608 may also include a graphics interface 614 that communicates with a display device 616. In one embodiment of the invention, the graphics interface 614 may communicate with the display device 616 via an accelerated graphics port (AGP). In an embodiment of the invention, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various examples of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some examples of the invention. In addition, the processor 602 and one or more other components discussed herein may be combined to form a single chip (e.g., to provide a System on Chip (SOC)). Furthermore, the graphics accelerator 616 may be included within the MCH 608 in other examples of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

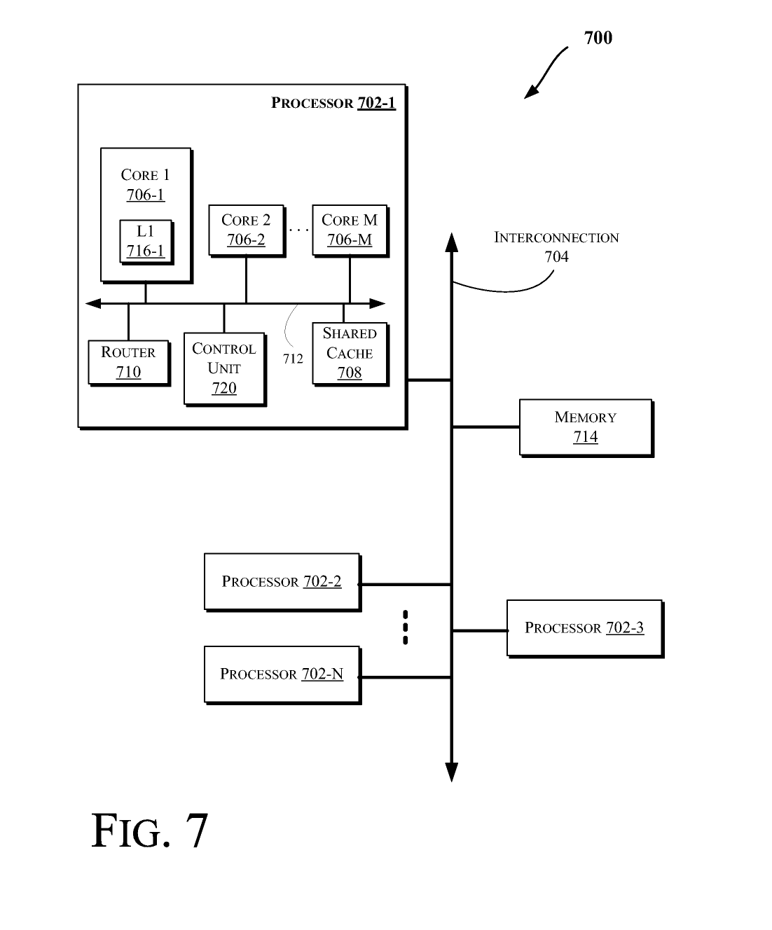

FIG. 7 illustrates a block diagram of a computing system 700, according to an embodiment of the invention. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an embodiment, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one embodiment, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an embodiment, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some examples, one or more of the cores 706 may include a level 1 (L1) cache 716-1 (generally referred to herein as “L1 cache 716”).

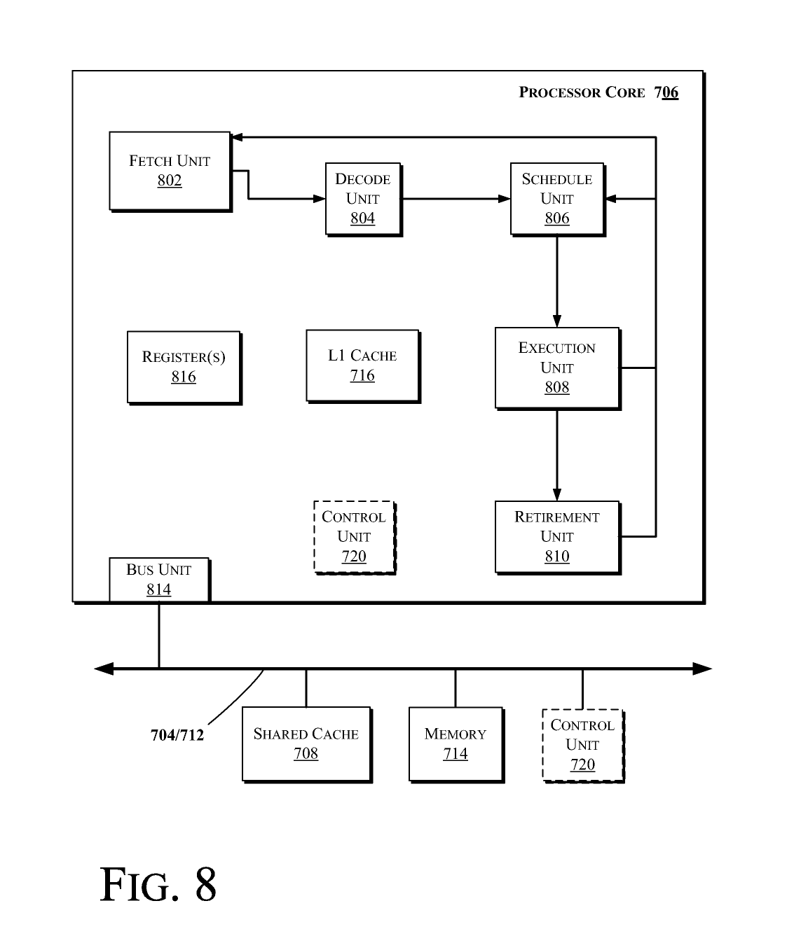

FIG. 8 illustrates a block diagram of portions of a processor core 706 and other components of a computing system, according to an embodiment of the invention. In one embodiment, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one embodiment, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an embodiment, the execution unit 808 may include more than one execution unit. The execution unit 808 may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit 808.

Further, the execution unit 808 may execute instructions out-of-order. Hence, the processor core 706 may be an out-of-order processor core in one embodiment. The core 706 may also include a retirement unit 810. The retirement unit 810 may retire executed instructions after they are committed. In an embodiment, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various examples the control unit 720 may be located elsewhere such as inside the core 706, coupled to the core via bus 704, etc.

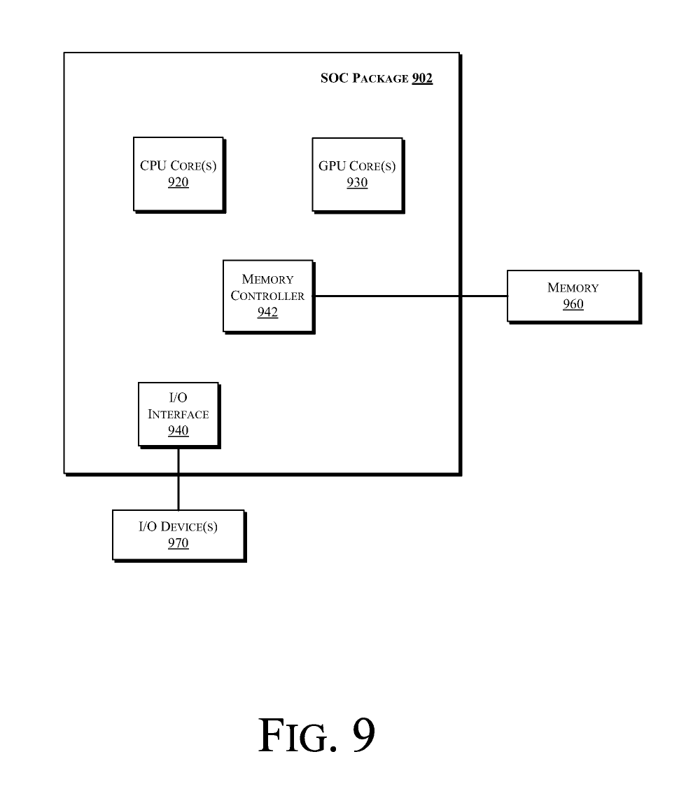

In some examples, one or more of the components discussed herein can be embodied as a System On Chip (SOC) device. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an embodiment, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

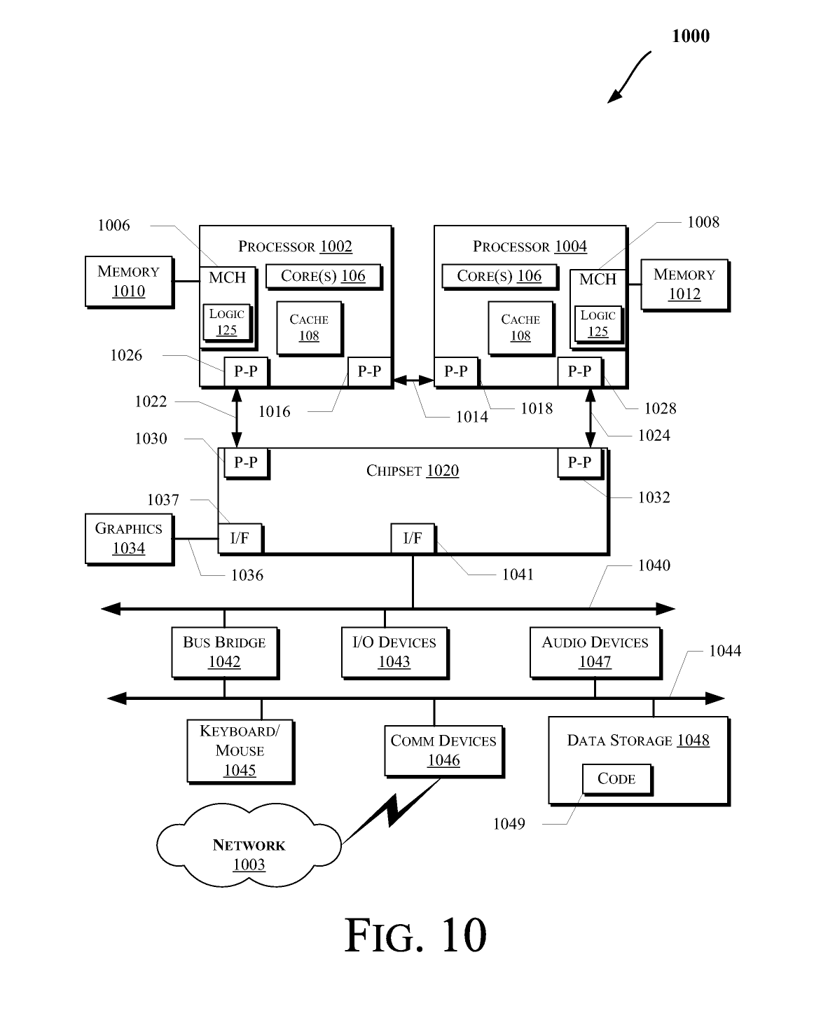

FIG. 10 illustrates a computing system 1000 that is arranged in a point-to-point (PtP) configuration, according to an embodiment of the invention. In particular, FIG. 10 shows a system where processors, memory, and input/output devices are interconnected by a number of point-to-point interfaces.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012.

In an embodiment, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

The chipset 1020 may communicate with a bus 1040 using a PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 803), audio I/O device, and/or a data storage device 1048. The data storage device 1048 (which may be a hard disk drive or a NAND flash based solid state drive) may store code 1049 that may be executed by the processors 1002 and/or 1004.

The following pertains to further examples.

Example 1 is a controller coupled to a processor unit, the controller comprising logic to detect a predicted a catastrophic event, and in response thereto, to block additional transactions on the processor unit, initiate a cache flush to flush data from a cache memory coupled to the processor unit to a memory controller buffer, block incoming data from the cache memory, and initiate a buffer flush to flush data from the memory controller buffer to a nonvolatile memory.

In Example 2, the subject matter of Example 1 can optionally include logic to place the processor unit in a low power state.

In Example 3, the subject matter of any one of Examples 1-2 can optionally include logic to force a non-snoop mode in the cache memory.

In Example 4, the subject matter of any one of Examples 1-3 can optionally include logic to release the block of incoming data and release the block on additional transactions on the processor unit.

In Example 5, the subject matter of any one of Examples 1-4 can optionally include an arrangement in which remove the processor from a low-power state.

In Example 6, the subject matter of any one of Examples 1-5 can optionally include logic to remove the cache memory from a non-snoop mode.

In Example 7 is an apparatus, comprising a processor comprising at least one processor unit and a controller coupled to the processor unit, the controller comprising logic to detect a predicted a catastrophic event, and in response thereto, to block additional transactions on the processor unit, initiate a cache flush to flush data from a cache memory coupled to the processor unit to a memory controller buffer, block incoming data from the cache memory, and initiate a buffer flush to flush data from the memory controller buffer to a nonvolatile memory

In Example 8, the subject matter of Example 7 can optionally include logic to place the processor unit in a low power state.

In Example 9, the subject matter of any one of Examples 7-8 can optionally include logic to force a non-snoop mode in the cache memory.

In Example 10, the subject matter of any one of Examples 7-9 can optionally include logic to release the block of incoming data and release the block on additional transactions on the processor unit.

In Example 11, the subject matter of any one of Examples 7-10 can optionally include an arrangement in which remove the processor from a low-power state.

In Example 12, the subject matter of any one of Examples 7-11 can optionally include logic to remove the cache memory from a non-snoop mode.

In Example 13, the subject matter of any one of Examples 7-12 can optionally include an arrangement in which the processor unit comprises at least one processor core and further comprising a volatile memory communicatively coupled to the at least one processor and a controller communicatively coupled to the volatile memory and comprising logic to receive a first transaction to operate on a first data element in a volatile memory, determine whether the first data element is to be stored in a nonvolatile memory, and in response to a determination that the first data element is to be stored in a nonvolatile memory, to forward the first transaction to the memory controller coupled to the nonvolatile memory.

In Example 14, the subject matter of any one of Examples 7-13 can optionally include logic to receive a transaction to operate on a second data element in a volatile memory determine whether the second data element is to be stored in a nonvolatile memory, and in response to a determination that the second data element is to be stored in a volatile memory, to drop the transaction.

In Example 15, the subject matter of any one of Examples 7-14 can optionally include logic to change a status of the first data element to an exclusive state.

Example 16 is an electronic device, comprising a nonvolatile memory device, a processor comprising at least one processor unit, and a controller coupled to the processor unit, the controller comprising logic to detect a predicted a catastrophic event, and in response thereto, to block additional transactions on the processor unit, initiate a cache flush to flush data from cache memory coupled to the processor unit to a memory controller buffer, block incoming data from the cache memory, and initiate a buffer flush to flush data from the memory controller buffer to a nonvolatile memory.

In Example 17, the subject matter of Example 16 can optionally include logic to place the processor unit in a low power state.

In Example 18, the subject matter of any one of Examples 16-17 can optionally include logic to force a non-snoop mode in the cache memory.

In Example 19, the subject matter of any one of Examples 16-18 can optionally include logic to release the block of incoming data and release the block on additional transactions on the processor unit.

In Example 20, the subject matter of any one of Examples 16-19 can optionally include an arrangement in which remove the processor from a low-power state.

In Example 21, the subject matter of any one of Examples 16-20 can optionally include logic to remove the cache memory from a non-snoop mode.

In Example 22, the subject matter of any one of Examples 16-21 can optionally include an arrangement in which the processor unit comprises at least one processor core and further comprising a volatile memory communicatively coupled to the at least one processor and a controller communicatively coupled to the volatile memory and comprising logic to receive a first transaction to operate on a first data element in a volatile memory, determine whether the first data element is to be stored in a nonvolatile memory, and in response to a determination that the first data element is to be stored in a nonvolatile memory, to forward the first transaction to the memory controller coupled to the nonvolatile memory.

In Example 23, the subject matter of any one of Examples 16-22 can optionally include logic to receive a transaction to operate on a second data element in a volatile memory determine whether the second data element is to be stored in a nonvolatile memory, and in response to a determination that the second data element is to be stored in a volatile memory, to drop the transaction.

In Example 24, the subject matter of any one of Examples 16-23 can optionally include logic to change a status of the first data element to an exclusive state.

In various examples of the invention, the operations discussed herein, e.g., with reference to FIGS. 1-10, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed herein.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some examples of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although examples of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. A controller coupled to a processor unit, the controller comprising logic to:
detect a predicted a catastrophic event, and in response thereto, to:
block additional transactions on the processor unit;
initiate a cache flush to flush data from a cache memory coupled to the processor unit to a memory controller buffer;
block incoming data from the cache memory; and
initiate a buffer flush to flush data from the memory controller buffer to a nonvolatile memory.

2. The controller of claim 1, wherein the logic to block additional transactions on the processor unit further comprises logic to:
place the processor unit in a low power state.

3. The controller of claim 1, wherein the logic to block incoming data from the cache memory further comprises logic to:
force a non-snoop mode in the cache memory.

4. The controller of claim 1, further comprising logic to:
release the block of incoming data; and
release the block on additional transactions on the processor unit.

5. The controller of claim 4, wherein the logic to release the block of incoming data further comprises logic to:
remove the processor from a low-power state.

6. The controller of claim 4, wherein the logic to release the block of incoming data further comprises logic to:
remove the cache memory from a non-snoop mode.

7. An apparatus, comprising:
a processor comprising at least one processor unit; and
a controller coupled to the processor unit, the controller comprising logic to:
detect a predicted a catastrophic event, and in response thereto, to:
block additional transactions on the processor unit;
initiate a cache flush to flush data from a cache memory coupled to the processor unit to a memory controller buffer;
block incoming data from the cache memory; and
initiate a buffer flush to flush data from the memory controller buffer to a nonvolatile memory.

8. The apparatus of claim 7, wherein the logic to block additional transactions on the processor unit further comprises logic to:
place the processor unit in a low power state.

9. The apparatus of claim 7, wherein the logic to block incoming data from the cache memory further comprises logic to:
force a non-snoop mode in the cache memory.

10. The apparatus of claim 7, further comprising logic to:
release the block of incoming data; and
release the block on additional transactions on the processor unit.

11. The apparatus of claim 10, wherein the logic to release the block of incoming data further comprises logic to:
remove the processor from a low-power state.

12. The apparatus of claim 10, wherein the logic to release the block of incoming data further comprises logic to:
remove the cache memory from a non-snoop mode.

13. The apparatus of claim 7, wherein the processor unit at least one processor core and further comprising;
a volatile memory communicatively coupled to the at least one processor; and
a controller communicatively coupled to the volatile memory and comprising logic to:
receive a first transaction to operate on a first data element in a volatile memory;
determine whether the first data element is to be stored in a nonvolatile memory, and in response to a determination that the first data element is to be stored in a nonvolatile memory, to:
forward the first transaction to the memory controller coupled to the nonvolatile memory.

14. The apparatus of claim 13, wherein the controller further comprises logic to:
receive a transaction to operate on a second data element in a volatile memory;
determine whether the second data element is to be stored in a nonvolatile memory, and in response to a determination that the second data element is to be stored in a volatile memory, to:
drop the transaction.

15. The apparatus of claim 13, wherein the controller further comprises logic to:
change a status of the first data element to an exclusive state.

16. An electronic device, comprising:
a nonvolatile memory device;
a processor comprising at least one processor unit; and
a controller coupled to the processor unit, the controller comprising logic to:
detect a predicted a catastrophic event, and in response thereto, to:
block additional transactions on the processor unit;
initiate a cache flush to flush data from cache memory coupled to the processor unit to a memory controller buffer;
block incoming data from the cache memory; and
initiate a buffer flush to flush data from the memory controller buffer to a nonvolatile memory.

17. The electronic device of claim 16, wherein the logic to block additional transactions on the processor unit further comprises logic to:
place the processor unit in a low power state.

18. The electronic device of claim 16, wherein the logic to block incoming data from the cache memory further comprises logic to:
force a non-snoop mode in the cache memory.

19. The electronic device of claim 16, further comprising logic to:
release the block of incoming data; and
release the block on additional transactions on the processor unit.

20. The electronic device of claim 19, wherein the logic to release the block of incoming data further comprises logic to:
remove the processor from a low-power state.

21. The electronic device of claim 19, wherein the logic to release the block of incoming data further comprises logic to:
remove the cache memory from a non-snoop mode.

22. The electronic device of claim 16, wherein the processor unit at least one processor core and further comprising;
a volatile memory communicatively coupled to the at least one processor; and
a controller communicatively coupled to the volatile memory and comprising logic to:
receive a first transaction to operate on a first data element in a volatile memory;
determine whether the first data element is to be stored in a nonvolatile memory, and in response to a determination that the first data element is to be stored in a nonvolatile memory, to:
forward the first transaction to the memory controller coupled to the nonvolatile memory.

23. The electronic device of claim 22, wherein the controller further comprises logic to:
receive a transaction to operate on a second data element in a volatile memory;
determine whether the second data element is to be stored in a nonvolatile memory, and in response to a determination that the second data element is to be stored in a volatile memory, to:
drop the transaction.

24. The electronic device of claim 22, wherein the controller further comprises logic to:
change a status of the first data element to an exclusive state.
